(19) United States
(12) Patent Application Publication
(10) Pub. No.: US 2003/0210029 A1
(43) Pub. Date: Nov. 13, 2003

(54) Coherent clock measurement unit

(76) Inventors: Billy Antheunisse, Rowlett, TX (US); Craig Lambert, Plano, TX (US); Dale Alan Heaton, Plano, TX (US)

Correspondence Address: TEXAS INSTRUMENTS INCORPORATED, P O BOX 655474, M/S 3999, DALLAS, TX, 75265

(21) Appl. No.: 10/141,473

(22) Filed: May 7, 2002

(51) Int. Cl. G01R 23/12

(52) U.S. Cl. 324/76.53

(57) ABSTRACT

A Coherent Clock Measurement Unit (50) that measures PLL jitter in a coherent manner includes a master clock circuit (52) which provides a master clock signal at a first clock frequency. A first clock divide circuit (54) couples to receive the master clock signal to provide as reference clock signal at a second clock frequency. The phase lock loop input of a device under test (10) connects to receive the reference clock signal. In addition, a second clock divide circuit (56) couples to receive the master clock signal to generate a re-arm clock signal at a third clock frequency. A test measurement unit (58), that is clocked using the re-arm clock signal, receives the signal transmitted at the phase lock loop output to measure a predetermined interval of the signal at a predetermined time based upon the re-arm clock signal. A capture memory (60), which is clocked by the re-arm clock signal, stores the output of the test measurement unit for subsequent retrieval and refinement by a processing unit having FFT analysis.

### FIELD OF THE INVENTION

The present invention relates to a method and structure for testing phased lock loop clock circuitry on an embedded core based system-on-chip (SoC), and more particularly, to a method and structure for measuring jitter in a coherent fashion.

### BACKGROUND OF THE INVENTION

Through advancements in semiconductor processing technology, Application Specific Integrated Circuit (ASIC) technology has evolved from a chip-set philosophy to an embedded core based System-on-chip (SoC) concept. An SoC integrated circuit (IC) includes various reusable functional blocks, such as digital signal processors (DSPs), interfaces, memory arrays, and microprocessors. Such predesigned functional blocks are commonly called “cores.”

FIG. 1 is a schematic diagram showing an example of inner structure of such an SoC IC as is illustrated in U.S. Pat. No. 6,249,893, which is incorporated by reference herein. In the example of FIG. 1, an SoC IC 10 includes a microprocessor core 12, a memory core 14, function specific cores 16-20, a phase lock loop (PLL) core 22, and a test access port (TAP) 24.

Clock measurement instruments are more critical in the SoC era of integrated circuits. In particular, as shown in FIG. 1, most CPU/DSP core based integrated circuits have phased locked loop (PLL) clock circuitry. Conventional testing of the PLL clock circuitry includes randomly reading clock measurements, storing these clock measurements, resetting these measurements and asynchronously re-arming the PLL clock circuit through software. RMS and long term jitter is measured in this asynchronous fashion by storing thousands of random sample measurements. The accuracy of the root mean square (RMS) and long term jitter measurements is proportional to the number of random sample measurements taken. Therefore, the greater number of sample measurements taken produces a greater accuracy of RMS and long term jitter measurements.

Thus, effective testing of this circuitry, however, is extremely time consuming when trying to achieve accurate measurements due to each measurement random nature. Literally, thousands of random measurements must be taken to get accurate jitter measurements which includes RMS jitter and long term jitter for the PLL clock circuit.

Thus, there exists a need for a method and structure for effective, efficient testing of PLL clock circuits on SoC ICs.

### SUMMARY OF THE INVENTION

To address the above-discussed deficiencies of phase lock loop test measurement equipment, the present invention teaches a Coherent Clock Measurement Unit (CCMU) that measures PLL jitter in a coherent manner. The CCMU includes a clock circuit which provides a master clock signal at a first clock frequency. A first clock divide circuit couples to receive the master clock signal to provide a reference clock signal at a second clock frequency. The phase lock loop input of a device under test connects to receive the reference clock signal. In addition, a second clock divide circuit couples to receive the master clock signal to generate a re-arm clock signal at a third clock frequency. A test measurement unit, that is clocked using the re-arm clock signal, receives the signal transmitted at the phase lock loop output to measure a predetermined interval of the signal at a predetermined time based upon the re-arm clock signal. A capture memory, which is clocked by the re-arm clock signal, stores the output of the test measurement unit for subsequent retrieval and refinement by successive approximation routine logic.

The advantages include but are not limited to a coherent clock measurement system that measures clock jitter using FFT analysis to provide an accurate measurement without having to take a large amount of samples. This system retrieves fewer samples than conventional asynchronous methods and, thereby, is faster. Using capture memory, the sampling system can read, store, reset and re-arm more samples in a shorter time without software intervention than a system having software intervention.

### BRIEF DESCRIPTION OF THE DRAWINGS

For a more complete understanding of the present invention and the advantages thereof, reference is now made to the following description taken in conjunction with the accompanying drawing in which like reference numbers indicate like features and wherein:

FIG. 1 illustrates a known schematic diagram of an inner structure of a large scale integrated circuit (LSI) which is also called a system-on-chip (SoC) IC having a plurality of embedded cores; and

FIG. 2 illustrates the PLL clock testing structure in accordance with the present invention.

### DETAILED DESCRIPTION OF PREFERRED EMBODIMENTS

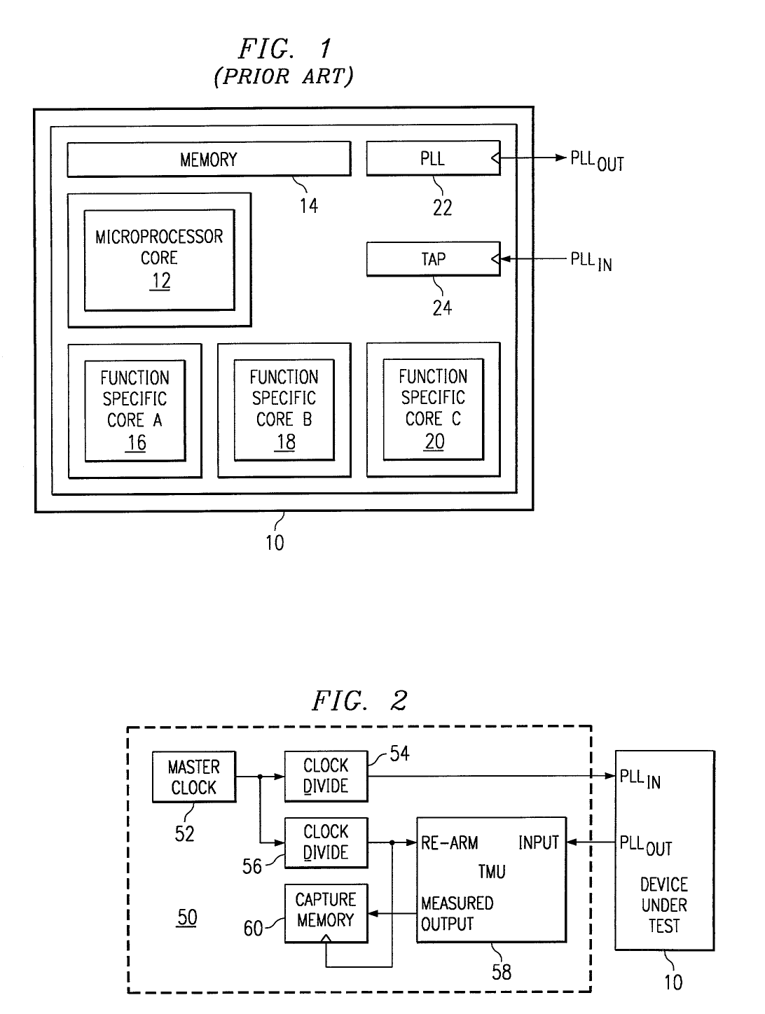

FIG. 2 illustrates the Coherent Clock Measurement Unit (CCMU) 50 in accordance with the present invention. CCMU 50 includes master clock circuit 52, clock divide circuits 54 and 56, test measurement unit 58 and capture memory 60. As shown the master clock circuit 52 provides a master clock signal having a first frequency to both clock divide circuits 54 and 56. Circuits 54 and 56 provide a reference and re-arm clock signal having a second and third frequency, respectively. The reference clock signal is fed into the PLL input of the device under test 10 as shown in FIG. 1, which may be any SoC IC. The PLL output of the device under test 10 is fed into the test measurement unit (TMU) 58 which measures a predetermined interval, such as a period, at any point in the signal provided by the PLL output. TMU 58 is clocked by the re-arm clock signal at the third frequency. Using the re-arm clock signal, TMU 58 shifts the measurement related to jitter on the pulse of the re-arm clock signal to the capture memory 60 where it is stored for subsequent retrieval and refinement by a processing unit (not shown) using FFT analysis.

In operation, the master clock signal at the first frequency, is divided down to supply the reference clock signal to PLL 22 embedded in the device under test 10 which, as a result, generates an output clock at the PLL output to be measured by TMU 58. In addition, the master clock signal is also divided down using clock divide circuit 56 to supply a re-arm signal to TMU 58. Capture memory 60 captures measured samples for later analysis without software intervention. This allows CCMU 50 to measure the PLL output clock at a specified frequency and store the data at a specific sampling rate.

Using Fast Fourier Transform (FFT) analysis on the resultant measurement data, the CCMU 50 provides measurement of long term jitter of PLL 22 since long term jitter is mostly modulated jitter or sine wave in nature. A Fourier clock measurement system requires an automatic measure, store, reset and re-arm clock measurement unit that is controlled by a clock coherent to the input clock of a device under test. Aligning with this requirement, CCMU 50 also provides a Fourier clock measurement system which requires less samples than the conventional test measurement system to get highly accurate measurements. In summary, CCMU 50 uses FFT analysis to determine RMS and long term jitter measurements with a minimal amount of measured samples.

The reader's attention is directed to all papers and documents which are filed concurrently with this specification and which are open to public inspection with this specification, and the contents of all such papers and documents are incorporated herein by reference.

All the features disclosed in this specification (including any accompany claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The terms and expressions which have been employed in the foregoing specification are used therein as terms of description and not of limitation, and there is no intention in the use of such terms and expressions of excluding equivalents of the features shown and described or portions thereof, it being recognized that the scope of the invention is defined and limited only by the claims which follow.

We claim:

1. An apparatus for measuring jitter of a phase lock loop circuit on a device under test in a coherent manner, the device under test having a phase lock loop input and a phase lock loop output, comprising:
a master clock circuit to provide a master clock signal at a first clock frequency;
a first clock divide circuit coupled to receive the master clock signal to generate a reference clock signal at a second clock frequency, the phase lock loop input coupled to receive the reference clock signal;
a second clock divide circuit coupled to receive the master clock signal to generate a re-arm clock signal at a third clock frequency;
a test measurement unit, having a first and a second input and an output, the first input coupled to receive the re-arm clock signal and the second input coupled to the phase lock loop output to measure a predetermined intervals of the signal from the phase lock loop output at predetermined time based upon the re-arm clock signal; and
a capture memory having an input, an clock input and an output, the input coupled to receive the output of the test measurement unit and the clock input coupled to receive the re-arm clock signal for clocking each input to store the measurements provided by the test measurement unit for subsequent retrieval and refinement.

2. An apparatus for measuring jitter of a device under test in a coherent manner as recited in claim 1, wherein the second frequency is less than the first frequency.

3. An apparatus for measuring jitter of a device under test in a coherent manner as recited in claim 1, wherein the third frequency is less than the first frequency.

4. An apparatus for measuring jitter of a device under test in a coherent manner as recited in claim 1, wherein the predetermined interval is a period of the master clock signal.

5. An method for measuring jitter of a phase lock loop circuit on a device under test in a coherent manner, the phase lock loop circuit having a phase lock loop input and a phase lock loop output, comprising:
generating a master clock signal using a master clock circuit;
dividing down the master clock signal into a reference clock signal having a second frequency;
dividing down the master clock signal into a re-arm clock signal having a third frequency;
applying the reference clock signal to the phase lock loop input of the device under test;
retrieving the signal generated at the phase lock loop output by the phase lock loop circuit;
measuring a predetermined interval of the retrieved signal at a predetermined time based upon the re-arm clock signal; and
storing the measurement in a capture memory.

6. The method for measuring jitter of a phase lock loop circuit on a device under test in a coherent manner as recited in claim 5, wherein the second frequency is less than the first frequency.

7. The method for measuring jitter of a phase lock loop circuit on a device under test in a coherent manner as recited in claim 5, wherein the third frequency is less than the first frequency.

8. The method for measuring jitter of a phase lock loop circuit on a device under test in a coherent manner as recited in claim 5, wherein the predetermined interval is a period of the master clock signal.
